(19) United States
(12) Patent Application Publication
(10) Pub. No.: US 2023/0168124 A1
(43) Pub. Date: Jun. 1, 2023

(54) LIGHT SOURCE, SPECTROSCOPIC ANALYSIS SYSTEM, AND SPECTROSCOPIC ANALYSIS METHOD

(71) Applicant: Tokyo Electron Limited, Tokyo (JP)

(72) Inventor: Yasutoshi UMEHARA, Tokyo (JP)

(21) Appl. No.: 17/906,891

(22) PCT Filed: Mar. 17, 2021
(86) PCT No.: PCT/JP2021/010880

§ 371 Date: Sep. 21, 2022

(30) Foreign Application Priority Data
Mar. 23, 2020 (JP) 2020-051432

(51) Int. Cl. G01J 3/10; G01J 3/02

(52) U.S. Cl. CPC G01J 3/10; G01J 3/0216; G01J 2003/102

(57) ABSTRACT

A spectroscopic analysis system includes a light source including a light emitting diode (51X), a wavelength converter (52X) configured to convert a wavelength of light output from the light emitting diode (51X), and a condenser (54X) configured to condense light output from the wavelength converter (52X), the light source including a mixing section configured to mix light output from the plurality of light emitting elements, and the wavelength of the light output from the plurality of light emitting elements being different, and a spectroscopic measurement section configured to acquire spectroscopic data by dispersing light reflected from an object on which the light source emits the light.

### TECHNICAL FIELD

The present disclosure relates to a light source, a spectroscopic analysis system, and a spectroscopic analysis method.

### BACKGROUND

Patent Document 1 describes a light emitting device including an LED chip and a color conversion member to improve light extraction to the outside. This light emitting device is used for lighting equipment and the like.

### CITATION LIST

### Non-Patent Document

[Patent Document 1] Japanese Unexamined Patent Application Publication No. 2009-105379

### SUMMARY

### Problem to Be Solved by the Invention

The present disclosure provides a light source and a spectroscopic analysis system that can be used for long-life and for wide-range film thickness measurements, and a spectroscopic analysis method.

### Means for Solving Problem

A light source according to one aspect of the present disclosure includes a light emitting diode, a wavelength converter configured to convert a wavelength of light output from the light emitting diode, and a condenser configured to condense light output from the wavelength converter.

### Effect of Invention

According to the present disclosure, it can be used for long-life and for wide-range film thickness measurements.

### BRIEF DESCRIPTION OF THE DRAWINGS

FIG. 1 is a schematic diagram illustrating an example of a spectroscopic analysis system.

FIG. 2 is a schematic diagram illustrating an example of a light source.

FIG. 3 is a schematic diagram illustrating an example of a light emitting element.

FIG. 4A is a graph indicating a spectrum of light reflected from a bare silicon wafer on which a pattern is not formed.

FIG. 4B is a graph indicating a spectrum for calibration.

FIG. 5 is a graph indicating a spectrum of light reflected from the bare silicon wafer after calibration.

FIG. 6 is a block diagram illustrating an example of a functional configuration of a control device.

FIG. 7 is a block diagram illustrating an example of a hardware configuration of the control device.

FIG. 8 is a flow diagram illustrating an example of control (a test of a wafer) performed by a control device.

FIG. 9 is a drawing illustrating an example of acquiring positions of optical spectrum data.

FIG. 10 is a flow diagram illustrating an example of control (an estimation of the film thickness based on color change) performed by the control device.

FIG. 11 is a flow diagram illustrating an example of control (an estimation of the film thickness based on the optical spectrum data) performed by the control device.

FIG. 12A is a graph indicating a spectrum of light reflected from the bare silicon wafer.

[FIG. 12B] FIG. 12B is a graph indicating a spectrum of light reflected from a silicon nitride film formed on the bare silicon wafer.

FIG. 13A is a graph indicating an absolute optical spectrum.

FIG. 13B is a graph indicating an absolute optical spectrum after a smoothing process.

FIG. 14A is a contour diagram illustrating results of measuring the film thickness by using an ellipsometer.

FIG. 14B is a contour diagram illustrating results of measuring the film thickness by using a test unit including the light source.

FIG. 15 is a graph indicating an example of a spectrum of light output from one light emitting element.

### DESCRIPTION OF EMBODIMENTS

In the following, an embodiment will be described specifically with reference to the attached drawings. In the present specification and drawings, components having substantially the same functional configuration are referenced by the same reference symbols, and duplicate descriptions may be omitted.

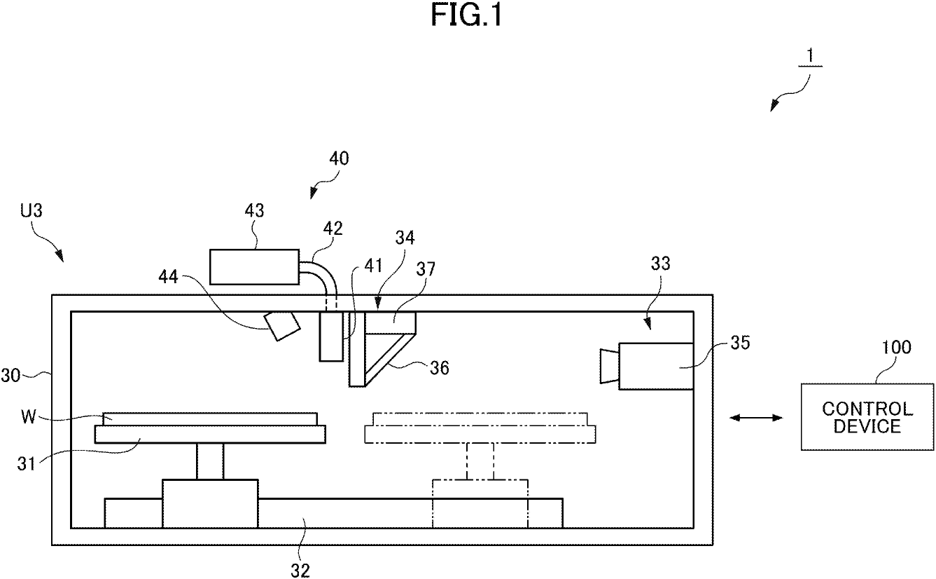

First, a spectroscopic analysis system including a light source according to the embodiment will be described. FIG. 1 is a schematic diagram illustrating an example of the spectroscopic analysis system. The spectroscopic analysis system 1 includes a control device 100 and a test unit U3.

### Test Unit

The test unit U3 acquires information related to a surface of a film formed on a substrate to be processed, for example, a semiconductor wafer W, and information related to the film thickness.

As illustrated in FIG. 1, the test unit U3 includes a housing 30, a holder 31, a drive section 32, an imager 33, a projector/reflector 34, and a spectroscopic measurement section 40. The holder 31 holds the wafer W horizontally. The drive section 32 uses, for example, an electric motor as a power source, and moves the holder 31 along a horizontal linear path. The drive section 32 can also rotate the holder 31 in a horizontal plane. The imager 33 includes a camera 35 such as a CCD camera, for example. The camera 35 is provided on one end side of the test unit U3 in the moving direction of the holder 31 and is directed at the other end side in the moving direction. The projector/reflector 34 projects light to an imaging range and guides light reflected from the imaging range to the camera 35 side. For example, the projector/reflector 34 includes a half mirror 36 and a light source 37. The half mirror 36 is provided at a position higher than the holder 31 and in the middle of the moving range of the drive section 32, and reflects the light coming from the lower side to the camera 35 side. The light source 37 is provided over the half mirror 36 and emits illumination light downward through the half mirror 36.

The spectroscopic measurement section 40 has a function of receiving and dispersing light incident from the wafer W and acquiring an optical spectrum. The spectroscopic measurement section 40 includes an incident section 41 that receives the light incident from the wafer W, a waveguide 42 that guides the light incident to the incident section 41, a spectroscope 43 that obtains the optical spectrum by dispersing the light guided by the waveguide 42, and a light source 44. The incident section 41 is configured so that the light from the center of the wafer W can be incident to the incident section 41 when the wafer W held in the holder 31 moves with the drive of the drive section 32. That is, the incident section 41 is provided at a position corresponding to the moving path of the center of the holder 31 moved by the drive of the drive section 32. Then, when the wafer W moves with the movement of the holder 31, the incident section 41 is attached so that the incident section 41 moves relatively with respect to the surface of the wafer W along the radial direction of the wafer W. This enables the spectroscopic measurement section 40 to acquire spectroscopic spectra at multiple locations along the radial direction of the wafer W, including the center portion of the wafer W. Additionally, by the drive section 32 rotating the holder 31, the spectroscopic measurement section 40 can acquire spectroscopic spectra at multiple positions along the circumferential direction of the wafer W. The waveguide 42 is formed of, for example, an optical fiber. The spectroscope 43 disperses the incident light to obtain the spectral spectrum including intensity information corresponding to each wavelength. The light source 44 emits the illumination light downward. This causes the light reflected from the wafer W to be incident to the spectroscope 43 through the incident section 41 and the waveguide 42.

Here, the wavelength range of the optical spectrum acquired by the spectroscope 43 can be, for example, a range of about 250 nm to 1200 nm, including the wavelength range of deep ultraviolet light and the wavelength range of visible light. By using a light source that emits light including the wavelength range of deep ultraviolet and visible light as the light source 44, the light reflected from the surface of the wafer W for the light coming from the light source 44 is dispersed by using the spectroscope 43, so that optical spectrum data including the wavelength range of deep ultraviolet and visible light can be acquired. The wavelength range of the optical spectrum acquired by the spectroscope 43 may include, for example, infrared light. Depending on the wavelength range of the optical spectrum data to be acquired, a suitable spectroscope and a suitable light source can be selected as the spectroscope 43 and the light source 44. For example, the light source 44 may be an irradiating unit including a light emitting element and a lens, or the light source 44 may include a light emitting element and a waveguide such as an optical fiber coaxial with the waveguide 42.

The test unit U3 operates as follows to acquire image data of the surface of the wafer W. First, the drive section 32 moves the holder 31. This causes the wafer W to pass under the half mirror 36. In this passing process, the light reflected from the surface of the wafer W is sequentially sent to the camera 35. The camera 35 forms an image of the reflected light from the surface of the wafer W and acquires the image data of the surface of the wafer W. When the film thickness of the film formed on the surface of the wafer W changes, the image data of the surface of the wafer W imaged by the camera 35 changes, for example, the color of the surface of the wafer W changes in accordance with the film thickness. That is, acquiring the image data of the surface of the wafer W corresponds to acquiring information related to the film thickness of the film formed on the surface of the wafer W. This point will be discussed later.

The image data acquired by the camera 35 is sent to the control device 100. In the control device 100, the film thickness of the film on the surface of the wafer W can be estimated based on the image data, and the estimated result is retained in the control device 100 as the test result.

At the same time as when the image data is acquired by the test unit U3, spectroscopic measurement is performed on the light from the surface of the wafer W being incident to the spectroscopic measurement section 40. When the drive section 32 moves the holder 31, the wafer W passes under the incident section 41. In this passing process, the light reflected from multiple positions on the surface of the wafer W is incident to the incident section 41 and is incident to the spectroscope 43 via the waveguide 42. The incident light is dispersed by the spectroscope 43 to acquire optical spectrum data. When the film thickness of the film formed on the surface of the wafer W changes, for example, the optical spectrum changes in accordance with the film thickness. That is, acquiring optical spectrum data of the surface of the wafer W corresponds to acquiring information related to the film thickness of the film formed on the surface of the wafer W. This point will be discussed later. The test unit U3 can perform the acquisition of the image data and the spectroscopic measurement in parallel. Therefore, the measurement can be performed in a shorter time in comparison with a case in which these are performed one at a time.

The optical spectrum data acquired by the spectroscope 43 is sent to the control device 100. In the control device 100, the film thickness of the film on the surface of the wafer W can be estimated based on the optical spectrum data, and the estimated result is retained in the control device 100 as the test result.

### Light Source

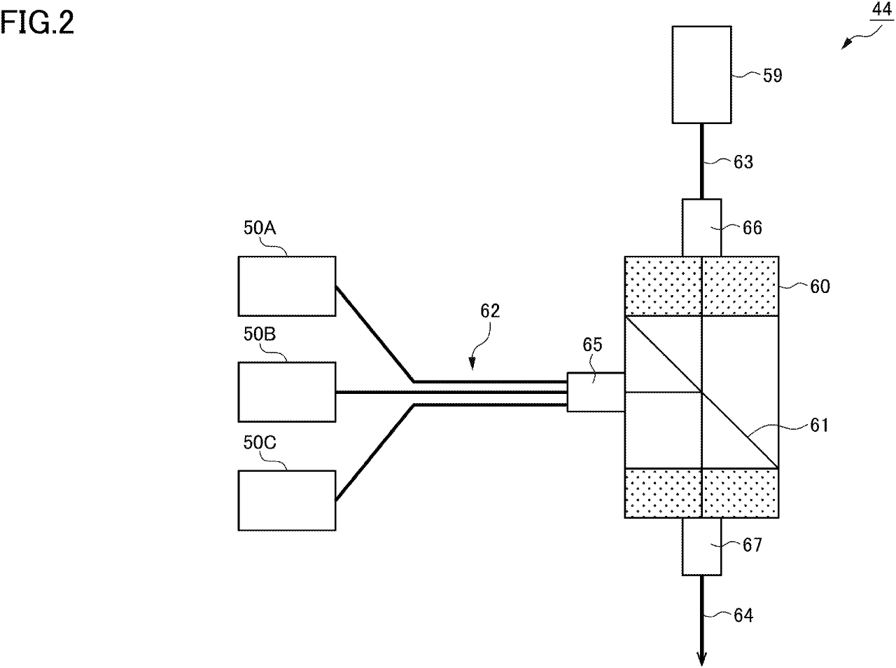

The light source 44 will be described. FIG. 2 is a schematic diagram illustrating an example of the light source.

As illustrated in FIG. 2, the light source 44 includes, for example, four light emitting elements 50A, 50B, 50C and 59 and a mixer 60 that mixes the light output from the light emitting elements 50A, 50B, 50C and 59. The light emitting elements 50A to 50C include a light emitting diode (LEDs) that outputs ultraviolet light, and the light emitting element 59 outputs white light. The mixer 60 includes a mirror filter 61. The light emitting elements 50A to 50C are connected to one end of an optical fiber bundle 62, and the other end of the optical fiber bundle 62 is connected to the mixer 60 via an SMA connector 65. The light emitting element 59 is connected to one end of an optical fiber 63, and the other end of the optical fiber 63 is connected to the mixer 60 via a connector 66. The mirror filter 61 is arranged to mix the light input from the optical fiber bundle 62 with the light input from the optical fiber 63. An optical fiber 64 is connected to the mixer 60 via an SMA connector 67. The light output from the mirror filter 61 propagates through the optical fiber 64. The mixer 60 is an example of a mixing section.

### Light Emitting Element

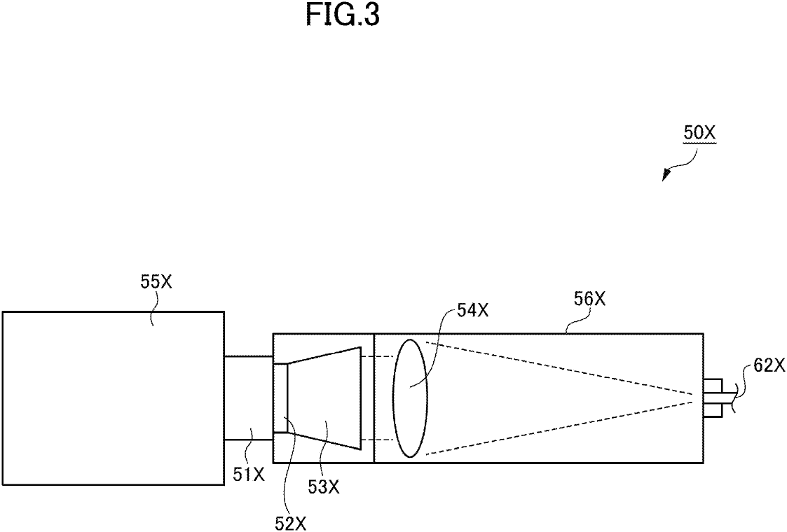

The light emitting elements 50A to 50C will be described. Hereinafter, the light emitting elements 50A to 50C may be collectively referred to as the light emitting elements 50X. FIG. 3 is a schematic diagram illustrating an example of the light emitting element.

As illustrated in FIG. 3, the light emitting element 50X includes an LED 51X, a fluorescent filter 52X, a total internal reflection (TIR) lens 53X, a condenser lens 54X, a heat sink 55X, and a housing 56X. The housing 56X accommodates the fluorescent filter 52X, the TIR lens 53X, and the condenser lens 54X. The optical fiber 62X included in the optical fiber bundle 62 is connected to the output end of the light emitting element 50X. The fluorescent filter 52X converts the wavelength of the light output from the LED 51X. The TIR lens 53X converts the light output from the fluorescent filter 52X into parallel light. The condenser lens 54X condenses the light transmitted through the TIR lens 53X. The light condensed by the condenser lens 54X is input to the optical fiber 62X. The heat sink 55X is attached to the LED 51X and releases heat generated in the LED 51X to the outside. The fluorescent filter 52X is an example of a wavelength converter and the condenser lens 54X is an example of a condenser.

The wavelength of the light output from the LED 51X differs between the light emitting elements 50A to 50C. The wavelength of the light output from the LED 51X is in the range of, for example, 250 nm to 700 nm. For example, at least one light emitting element among the light emitting elements 50A to 50C includes the LED 51X that outputs light having a wavelength of 350 nm or less. That is, at least one light emitting element among the light emitting elements 50A to 50C includes the LED 51X that outputs ultraviolet light.

The fluorescent filter 52X contains, for example, a pellet of a phosphor. The fluorescent filter 52X may include a film formed by the aggregation of glass powders to which phosphor nanoparticles are attached. The fluorescent filter 52X may include a film of silicone resin in which phosphor nanoparticles are dispersed. The phosphor is, for example, LaPO₄: Ce³⁺ or LaMgAl₁₁O₁₉ : Ce³⁺) . The fluorescent filter 52X preferably contains multiple kinds of phosphors. By containing multiple kinds of phosphors, a spectrum of the light output through the fluorescent filter 52X can be smoothed. The fluorescent filter 52X may contain a single kind of phosphors. Additionally, the fluorescent filter 52X preferably includes glass that retains phosphor particle. Glass is less likely to deteriorate than resin such as silicone resin, and especially when the wavelength of the light output by LED 51X is short, the resistance of glass becomes remarkable. The fluorescent filter 52X may be formed to seal the emitting surface of the LED 51X. The shape of the fluorescent filter 52X may be, for example, a plate.

Here, the number of the light emitting elements 50X connected to the optical fiber bundle 62 is not limited. For example, four light emitting elements 50X may be connected to the optical fiber bundle 62.

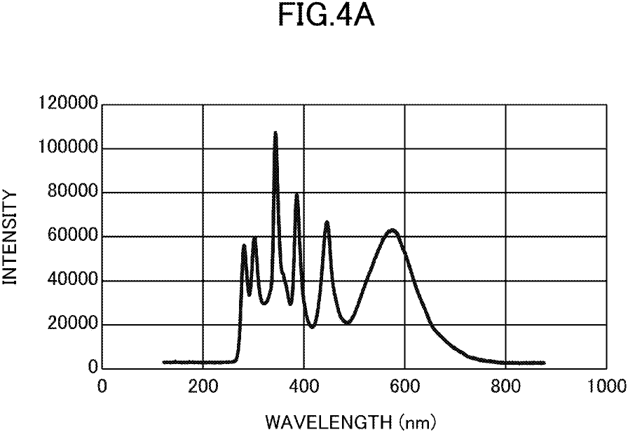

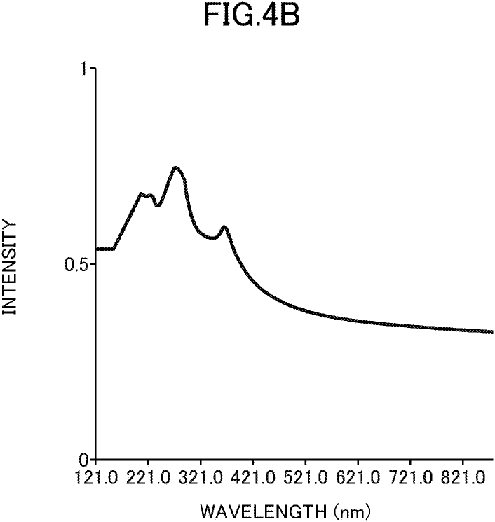

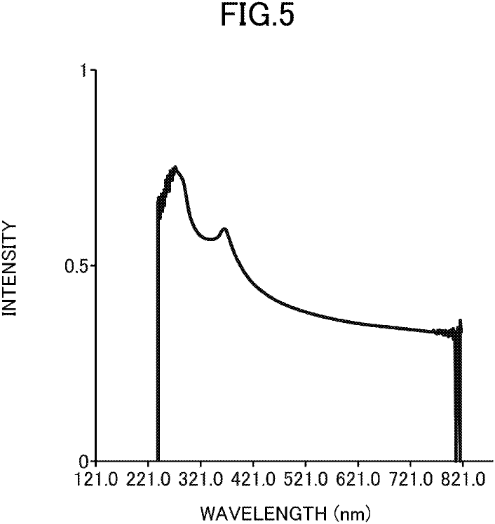

An example of a synthetic spectrum obtained when four light emitting elements 50X and one light emitting element 59 are connected to the mixer 60 will be described. FIG. 4A is a graph indicating the spectrum of the light reflected from a bare silicon wafer on which a pattern is not formed. FIG. 4B is a graph indicating a spectrum for calibration. FIG. 5 is a graph indicating a spectrum of the light reflected from the bare silicon wafer after calibration. Here, the wavelengths of the LEDs 51X included in the four light emitting elements are 285 nm, 340 nm, 365 nm, and 385 nm, respectively. The output power of the LED 51X that outputs 285 nm light is about 400 pW. The output power of the LED 51X that outputs 340 nm light is about 0.7 mW. The output power of the LED 51X that outputs 365 nm light is about 4 mW. The output power of the LED 51X that outputs 385 nm light is about 6 mW. The output power of the LED included in the light emitting element 59 that outputs white light is about 3 mW.

As illustrated in FIG. 4A, a light source in which four light emitting elements 50X and one light emitting element 59 are connected to the mixer 60 has a wide wavelength band. Therefore, as illustrated in FIG. 5, an absolute reflection spectrum having a wide wavelength band can be obtained as the spectrum of the light reflected from the bare silicon wafer after calibration.

The wavelength of the light output by the light source 44 is not particularly limited, and the light source 44 may output light having a wavelength of 250 nm to 1200 nm, for example. The wavelength band of the light output by the light source 44 preferably includes a wavelength band of 250 nm to 750 nm.

### Control Device

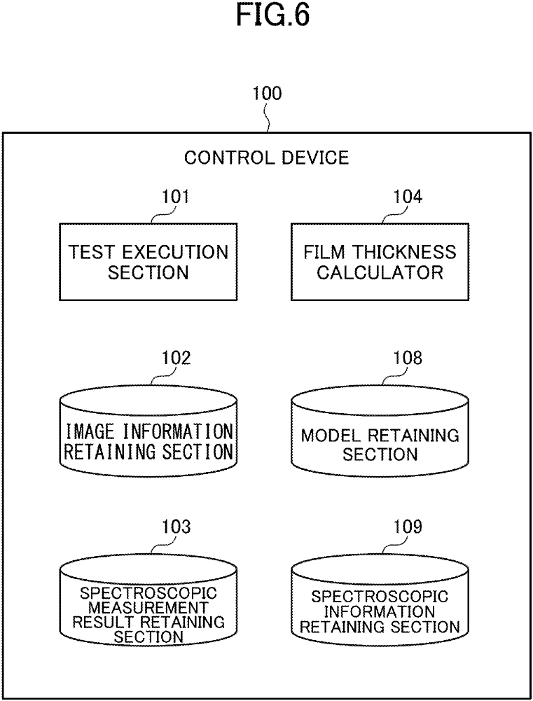

An example of the control device 100 will be described in detail. FIG. 6 is a block diagram illustrating an example of a functional configuration of the control device. The control device 100 controls each element included in the test unit U3.

As illustrated in FIG. 6, the control device 100 includes a test execution section 101, an image information retaining section 102, a spectroscopic measurement result retaining section 103, a film thickness calculator 104, a model retaining section 108, and a spectroscopic information retaining section 109, as the functional configuration.

The test execution section 101 has a function of controlling an operation related to the test of the wafer W in the test unit U3. As a result of the test in the test unit U3, the image data and the optical spectrum data are acquired.

The image information retaining section 102 has a function of acquiring and retaining the image data in which the surface of the wafer W is imaged from the imager 33 of the test unit U3. The image data retained in the image information retaining section 102 is used to estimate the film thickness of the film formed on the wafer W.

The spectroscopic measurement result retaining section 103 has a function of acquiring and retaining the optical spectrum data related to the surface of the wafer W from the spectroscope 43 of the test unit U3. The optical spectrum data retained in the spectroscopic measurement result retaining section 103 is used to estimate the film thickness of the film formed on the wafer W.

The film thickness calculator 104 has a function of calculating the film thickness of the film formed on the wafer W based on the image data retained in the image information retaining section 102 and the optical spectrum data retained in the spectroscopic measurement result retaining section 103. The procedure of calculating the film thickness will be described later in detail.

The spectroscopic information retaining section 109 has a function of retaining the spectroscopic information to be used in calculating the film thickness from the optical spectrum data. The optical spectrum data acquired in the test unit U3 changes depending on the type and thickness of the film formed on the surface of the wafer W. Thus, information related to a correspondence relation between the film thickness and the optical spectrum is retained in the spectroscopic information retaining section 109. For example, the optical spectrum data related to the surface of a lower layer film such as a bare silicon wafer is acquired in advance, and the spectroscopic information retaining section 109 retains this optical spectrum data as reference data. The film thickness calculator 104 estimates the film thickness with respect to the wafer W to be tested (a target substrate) based on the information retained in the spectroscopic information retaining section 109.

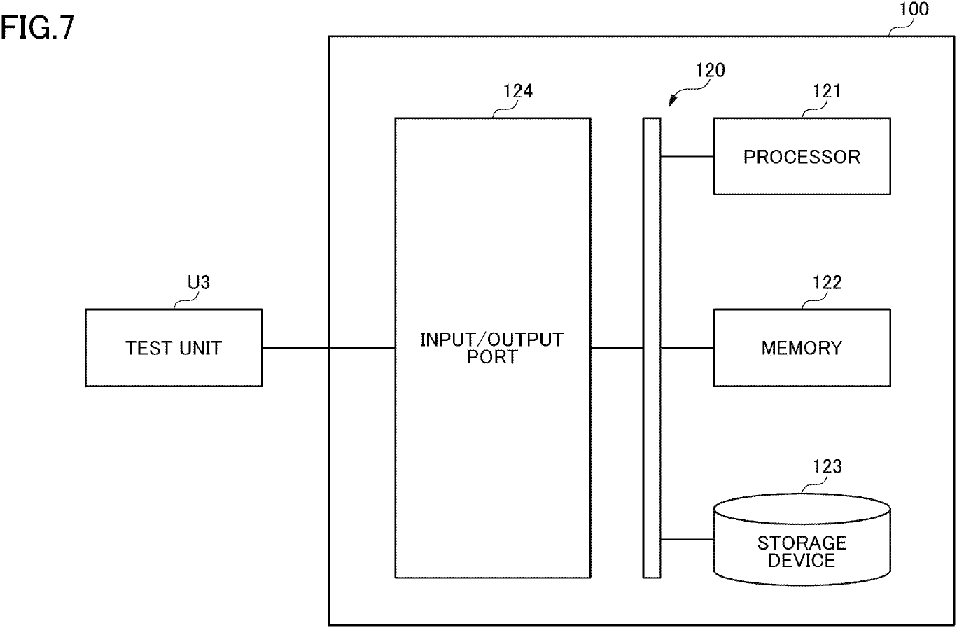

The control device 100 is configured by one or more control computers. FIG. 7 is a block diagram illustrating an example of a hardware configuration of the control device. For example, the control device 100 includes a circuit 120 illustrated in FIG. 7. The circuit 120 includes one or more processors 121, a memory 122, a storage device 123, and an input/output port 124. The storage device 123 includes a storage medium that can be read by a computer, such as a hard disk, for example. The storage medium stores a program for causing the control device 100 to execute a process processing procedure described later. The storage medium may be a removable medium such as a nonvolatile semiconductor memory, a magnetic disk, or an optical disk. The memory 122 temporarily stores the program loaded from the storage medium of the storage device 123 and a result of an operation performed by the processor 121. The processor 121 configure each of the function modules described above by executing the above program in cooperation with the memory 122. The input/output port 124 inputs electrical signals from a member to be controlled and outputs electrical signals to the member according to instructions from the processor 121.

Here, the hardware configuration of the control device 100 is not necessarily limited to a configuration in which each functional module is configured by a program. For example, each functional module of the control device 100 may be configured by a dedicated logic circuit or an application specific integrated circuit (ASIC) in which the dedicated logic circuit is integrated.

Here, some of the functions illustrated in FIG. 6 may be provided in a device different from the control device 100 that controls the test unit U3. When some functions are provided in an external device different from the control device 100, the external device and the control device 100 cooperate to achieve the functions described in the following embodiment. In such a case, the external device having functions corresponding to the control device 100 described in the present embodiment and the remainder of the spectroscopic analysis system 1 described in the present embodiment can function as a spectroscopic analysis system integrally.

### Substrate Test Method

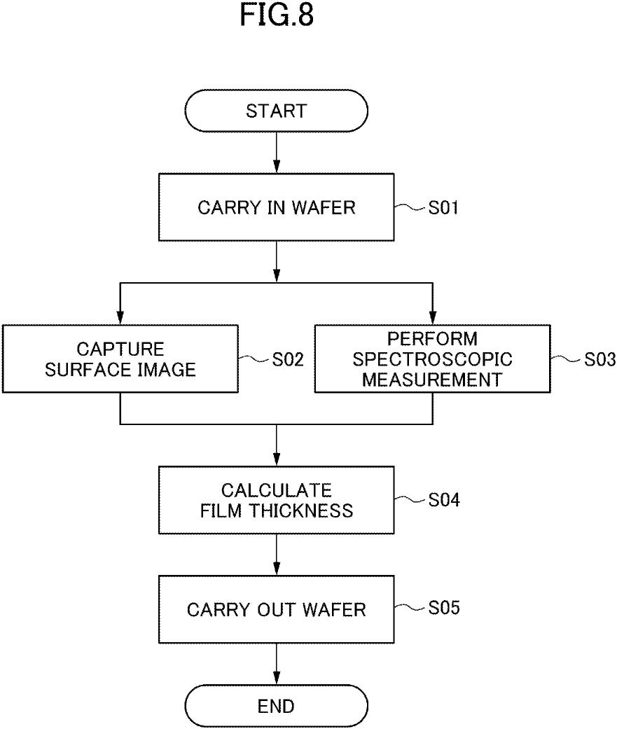

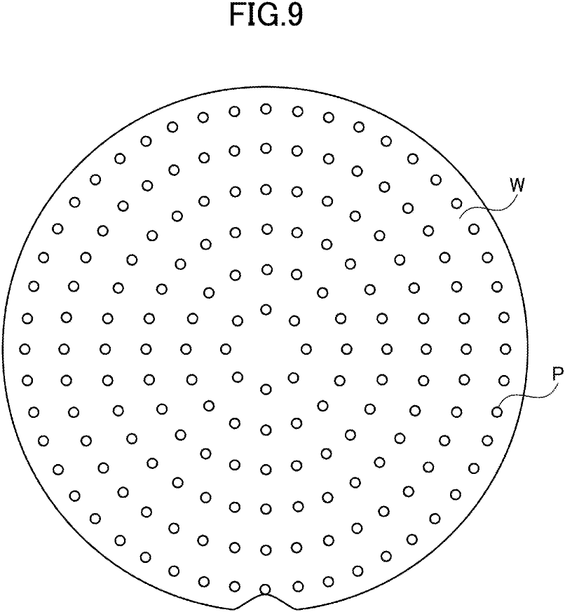

Next, the substrate test method performed by the control device 100 will be described with reference to FIGS. 8 to 11. FIG. 8 is a flow diagram illustrating an example of control (a test of a wafer) performed by the control device. FIG. 9 is a drawing illustrating an example of acquiring positions of the optical spectrum data. The substrate test method is a method related to the test of the wafer W, on which a film has been deposited, performed in the test unit U3. The test unit U3 checks whether a desired film deposition has been performed on the wafer W on which the film has been deposited. Specifically, the surface condition of the film formed on the wafer W and the film thickness are evaluated. The test unit U3 includes, for example, the imager 33 and the spectroscopic measurement section 40 as described above, so that the image data in which the surface of the wafer W is imaged by the imager 33 and the optical spectrum data of the surface of the wafer W obtained by the spectroscopic measurement section 40 can be acquired. The control device 100 evaluates the film deposition state based on these data.

First, the control device 100 performs step S01. In step S01, the wafer W on which the film has been deposited is carried into the test unit U3. The wafer W is held in the holder 31.

Next, the test execution section 101 of the control device 100 performs step S02 (an image acquisition step). In step S02, the surface of the wafer W is imaged by the imager 33. Specifically, the surface of the wafer W is imaged by the imager 33 while the holder 31 is moved in a predetermined direction by the drive of the drive section 32. This allows the image data related to the surface of the wafer W to be acquired in the imager 33. The image data is retained in the image information retaining section 102 of the control device 100.

Here, simultaneously with performing step S02, the test execution section 101 of the control device 100 performs step S03 (a spectroscopic measurement step). In step S03, the spectroscopic measurement is performed at multiple positions on the surface of the wafer W by the spectroscopic measurement section 40. As described above, the incident section 41 of the spectroscopic measurement section 40 is provided on the path through which the center of the wafer W held by the holder 31 passes when the holder 31 moves, so that the optical spectrum can be acquired at multiple positions along the radial direction of the wafer W including the center portion. Additionally, by the drive section 32 rotating the holder 31, the spectroscopic measurement section 40 can acquire the optical spectrum at multiple positions along the circumferential direction of the wafer W. Therefore, as illustrated in FIG. 9, the light reflected from multiple positions, where, for example, multiple lines passing through the center of the wafer W and multiple concentric circles intersect, is incident to the incident section 41. The spectroscope 43 measures the optical spectrum of the light incident to the incident section 41. As a result, the spectroscope 43 acquires, for example, P pieces of optical spectrum data corresponding to multiple measurement positions P illustrated in FIG. 9 as multiple locations, for example, 49 pieces of optical spectrum data. As described, the optical spectrum data related to the surface of the wafer W at multiple positions can be acquired by using the spectroscope 43. Here, the locations and the number of measurement positions P can be appropriately changed depending on the interval between spectroscopic measurements performed by the spectroscope 43 and the moving speed of the wafer W moved by the holder 31. The optical spectrum data acquired by the spectroscope 43 is retained in the spectroscopic measurement result retaining section 103 of the control device 100.

The film thickness calculator 104 of the control device 100 performs step S04. In step S04, the film thickness of the film on the surface of the wafer W is calculated based on the image data related to the surface of the wafer W or the optical spectrum data obtained by the spectroscopic measurement.

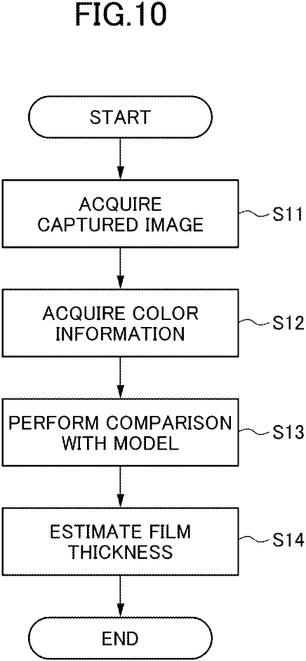

The procedure of calculating the film thickness by using image data will be described with reference to FIG. 10. FIG. 10 is a flow diagram illustrating an example of control (the estimation of the film thickness based on the color change) performed by the control device. In calculating the film thickness by using the image data, a film thickness model retained in the model retaining section 108 is used. The film thickness model is a model for calculating the film thickness based on the information related to the color change of each pixel in the image data obtained by imaging the surface of the wafer W when a predetermined film is formed (the color change before and after the formation of the predetermined film), and is a model representing the correspondence relation between the information related to the color change and the film thickness. By retaining such a model in advance in the model retaining section 108, the information related to the color changes at multiple positions of the image data is acquired, so that the film thickness can be estimated based on the color change. For both the wafer W on which each processing up to the previous stage has been performed and the wafer W on which the predetermined film has been formed subsequently, the image data is acquired by imaging the surface of the wafer W to identify how the color has changed. Additionally, the film thickness of the wafer on which the film has been deposited under the same conditions is measured. This can identify the correspondence relation between the film thickness and the color change. By repeating this measurement while changing the film thickness, the correspondence relation between the information related to the color change and the film thickness can be obtained.

The method for calculating the film thickness based on the image data is, specifically, as illustrated in FIG. 10. First, the captured image data is acquired (step S11), and then the information related to the color change of each pixel is acquired from the image data (step S12). In order to acquire the information related to the color change, a process of calculating the difference from the image data on which the film is not deposited yet can be performed. Then, a comparison with the film thickness model retained by the model retaining section 108 is performed (step S13). This can estimate the film thickness of an area imaged at the pixel can be estimated for each pixel (step S14). This can estimate the film thickness at each pixel, that is, at multiple positions on the surface of the wafer W.

Here, the calculation (the estimation) of the film thickness based on the image data described above can be performed when the film formed on the wafer W is relatively thin (for example, about 500 nm or less), but it is difficult when the film thickness increases. This is because as the film thickness increases, the color change with respect to the change in film thickness decreases, and thus it becomes difficult to accurately estimate the film thickness based on the information related to the color change. Therefore, when a film having a large thickness is formed, the estimation of the film thickness is performed based on the optical spectrum data.

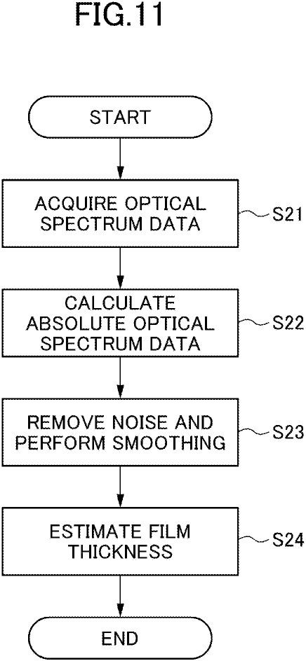

The procedure of calculating the film thickness by using the optical spectrum data will be described with reference to FIG. 11. FIG. 11 is a flow diagram illustrating an example of control (the estimation of the film thickness based on the optical spectrum data) performed by the control device. The calculation of the film thickness by using the optical spectrum data uses the change in the reflectivity in accordance with the film thickness of the surface of the film. When the light is emitted on the surface of the wafer on which the film is formed, the light is reflected at the surface of a topmost film or at the interface between the topmost film and a lower layer of the topmost film (the film or the wafer). Then, such light is emitted as the reflected light. That is, the reflected light includes light of two components with different phases. Additionally, as the surface film thickness increases, the phase difference increases. Therefore, when the film thickness changes, the degree of interference between the light reflected on the surface of the film and the light reflected at the interface with the lower layer changes. That is, the shape of the optical spectrum of the reflected light changes. The change in the optical spectrum in accordance with the film thickness can be theoretically calculated. Therefore, in the control device 100, the information related to the shape of the optical spectrum in accordance with the film thickness of the film formed on the surface is stored in advance. Then, the optical spectrum of the reflected light obtained by irradiating the actual wafer W with light is compared with the information stored in advance. This can estimate the film thickness of the film on the surface of the wafer W. The information related to the relation between the film thickness and the shape of the optical spectrum that is used to estimate the film thickness is retained in the spectroscopic information retaining section 109 of the control device 100.

The method of calculating the film thickness based on the optical spectrum data is as illustrated in FIG. 11, specifically. First, the result of the spectroscopic measurement, i.e., the optical spectrum data, is acquired (step S21). Then, referring to the information retained in the spectroscopic information retaining section 109, absolute optical spectrum data of the film to be measured is calculated based on the optical spectrum data (step S22). Then, noise contained in the absolute optical spectrum data is removed and smoothing is performed (step S23). For the noise removal and smoothing processing, for example, a Savitzky-Golay filter, a moving average filter, or a Spline smoothing filter can be used. Weight coefficient optimization by specifying the wavelength region of the optical spectrum may be used for the noise removal and smoothing processing. Next, a predetermined wavelength region, for example, a wavelength region of 270 nm to 700 nm, is extracted from the absolute optical spectrum data obtained by step S23, and the film thickness can be estimated based on the data of the extracted wavelength region (step S24). This can estimate the film thickness for each optical spectrum data, that is, at multiple positions on the surface of the wafer W. By calculating the film thickness based on each optical spectrum data, information related to the distribution of the film thickness on the surface of the wafer W can be obtained.

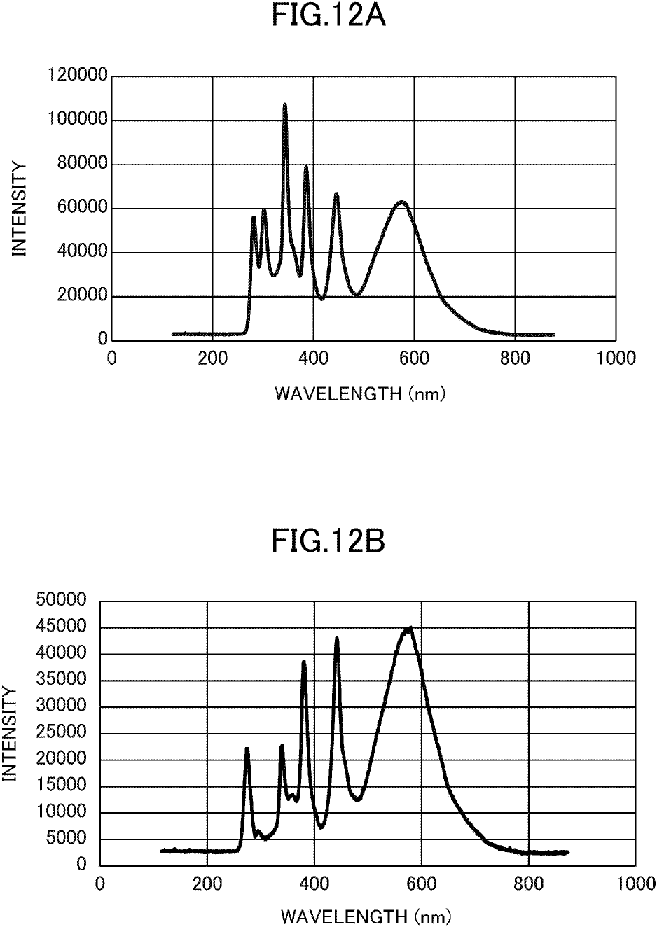

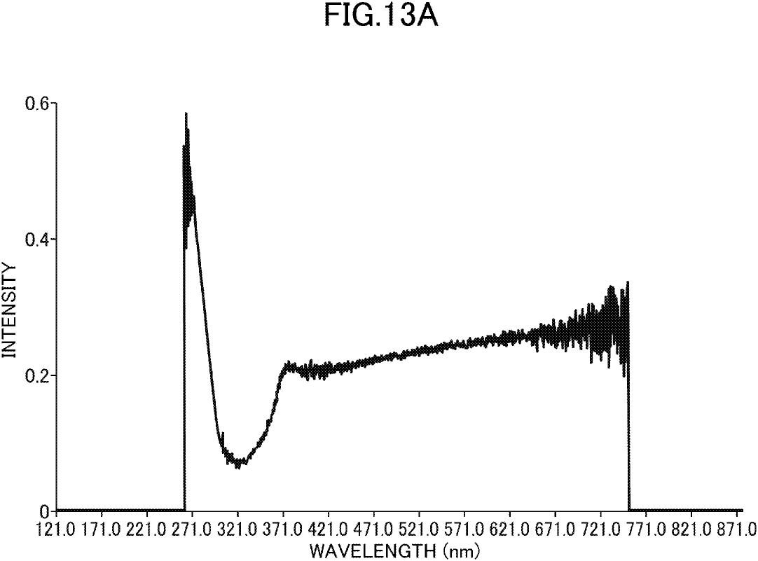

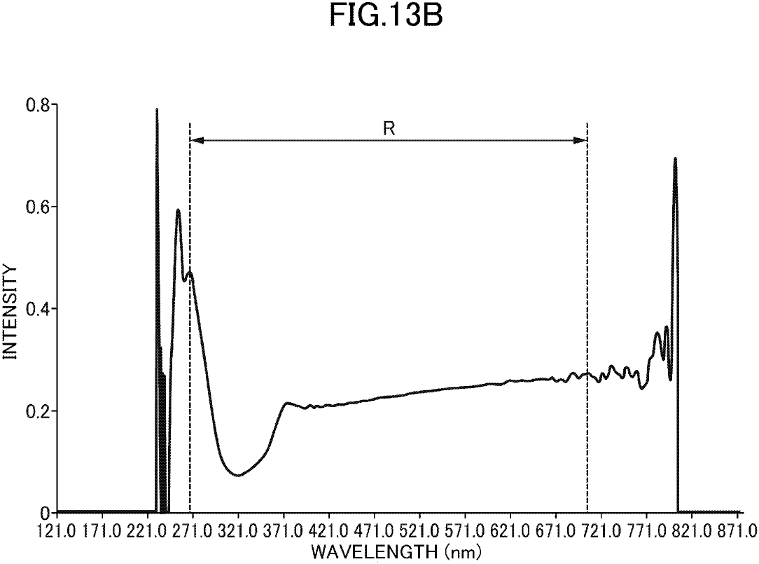

Here, the processing of steps S21 to S24 will be described with reference to an example. The example assumes that the thickness of a silicon nitride film formed on a bare silicon wafer is measured. FIG. 12A is a graph indicating the spectrum of the light reflected from the bare silicon wafer, and FIG. 12B is a graph indicating a spectrum of the light reflected from the silicon nitride film formed on the bare silicon wafer. FIG. 13A is a graph indicating an absolute optical spectrum, and FIG. 13B a graph indicating an absolute optical spectrum after the smoothing process.

In the example, the spectroscopic information retaining section 109 retains the optical spectrum data illustrated in FIG. 12A in advance. In step S21, the optical spectrum data illustrated in FIG. 12B is acquired. In step S22, by referring to the optical spectrum data illustrated in FIG. 12A, the absolute optical spectrum data of the silicon nitride film illustrated in FIG. 13A is calculated from the optical spectrum data illustrated in FIG. 12B. In step S23, the noise included in the absolute optical spectrum data is removed and smoothing is performed. As a result, the absolute optical spectrum data as illustrated in FIG. 13B is obtained. Then, in step S24, the film thickness is estimated based on the absolute optical spectrum data in a wavelength region R between 270 nm and 700 nm in FIG. 13B.

Here, when the film thickness is estimated based on the optical spectrum data, the acquisition of image data (step S02) may be omitted. In this case, the acquisition of the image data by the imager 33 is not required, and it may be configured to estimate the film thickness and evaluate the film deposition state based on only the optical spectrum data.

Returning to FIG. 8, after the calculation of the film thickness (step S04), the test execution section 101 of the control device 100 performs step S05. In step S05, the wafer W is carried out from the test unit U3. The wafer W that is carried out is sent, for example, to a processing module at a subsequent stage.

As described, the film thickness of the film to be measured formed on the wafer W is measured.

### Function

In the spectroscopic analysis system 1, the light source 44 includes the plurality of light emitting elements 50X (50A to 50C). Furthermore, the wavelength of the light output from the LED 51X included in the light emitting elements 50X differs between the plurality of light emitting elements 50X. Thus, the light source 44 can emit light in a wide band. Therefore, the system can be used for the film thickness measurement in a wide range. Additionally, by using an LED that emits ultraviolet or deep ultraviolet light with a wavelength of 350 nm or less as the LED 51X, ultraviolet or deep ultraviolet light can be included in the light emitted by the light source 44. Emitting light with a shorter wavelength enables the thickness of a thinner film to be measured with high accuracy. Furthermore, the lifetime of an LED, for example, 10,000 hours or longer, is significantly longer than the lifetime of a deuterium (D2)/halogen light source or an Xe light source, and the LED can operate continuously over a long period of time. Additionally, the wavelength spectrum reproducibility of the LED is better than the wavelength spectrum stability of the Xe lamp source. Furthermore, pulse drive is difficult for the Xe lamp light source, while pulse drive is easy for the LED.

The spectroscopic analysis system 1 including the light source 44 can be used, for example, by being built into a film deposition apparatus in which the film deposition and the film thickness measurement are performed. Examples of the film deposition apparatus include a coating and developing apparatus, a chemical vapor deposition (CVD) apparatus, a sputtering apparatus, a vapor deposition apparatus, and an atomic layer deposition (ALD) apparatus. The spectroscopic analysis system 1 including the light source 44 can be used, for example, by being built into an etching apparatus in which the etching and the film thickness measurement are performed. Examples of the etching apparatus include a plasma etching apparatus and an atomic layer etching (ALE) apparatus. Additionally, the spectroscopic analysis system may be arranged independently of the film deposition apparatus or the etching apparatus and may communicate the measurement result to the film deposition apparatus or the etching apparatus.

When the spectroscopic analysis system 1 is built into the film deposition apparatus or the etching apparatus, the operation of the film deposition apparatus is stopped when the light source 44 is replaced, but the replacement frequency can be reduced because the light source 44 has a long life.

Additionally, the light source 44 includes the light emitting element 59 that outputs white light, so that the thickness of a relatively thick film can be measured.

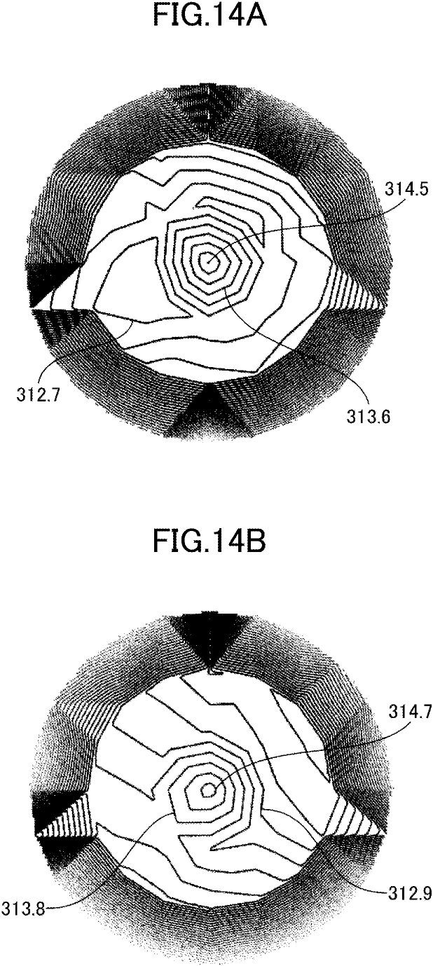

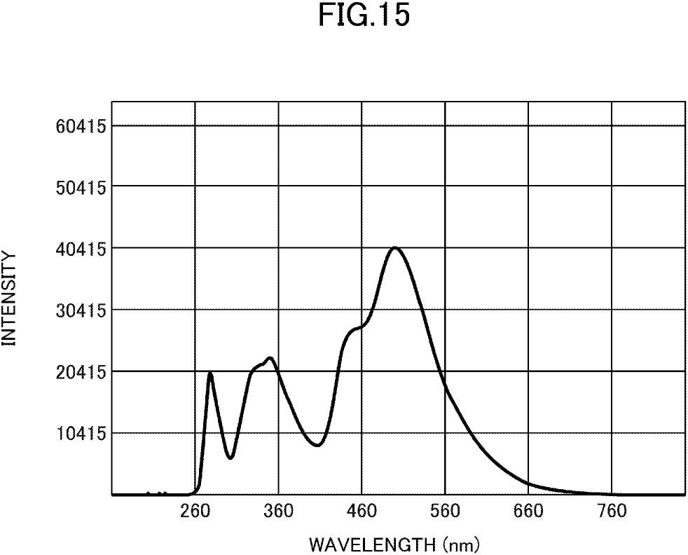

Here, an example of the measurement will be described. In the example, a silicon nitride film having a thickness of 30 nm was formed on a bare silicon wafer, and the film thickness measurement using an ellipsometer and the film thickness measurement using the test unit U3 including the light source 44 were performed. FIG. 14A is a contour diagram illustrating a result of the film thickness measurement using the ellipsometer, and FIG. 14B is a contour diagram illustrating a result of the film thickness measurement using the test unit U3 including the light source 44. The values in FIG. 14A and FIG. 14B are the film thickness (Å).

As illustrated in FIG. 14A and FIG. 14B, the film thickness measurement using the test unit U3 including the light source 44 can achieve the same level of accuracy as the film thickness measurement using the ellipsometer. The difference between them was 0.3 nm in root mean square (RMS). Additionally, the time required to measure the film thickness at one position is about 20 msec for the film thickness measurement using the ellipsometer, while the time is only about 5 msec for the film thickness measurement using the test unit U3 including the light source 44. That is, the measurement time can be shortened according to the film thickness measurement using the test unit U3 including the light source 44.

Here, the number of light emitting elements 50X included in the light source 44 need not be multiple, and even if the number of light emitting elements 50X included in the light source 44 is one, the light emitting element 50X can be used for the film thickness measurement in a wide range because the light emitting element 50X includes the LED 51X, the fluorescent filter 52X, and the condenser lens 54X. Additionally, the light source 44 and the incident section 41 may be integrally configured. FIG. 15 is a graph indicating an example of the spectrum of the light output from one light emitting element 50X.

The light source can be used for applications other than the spectroscopic system.

Although the preferred embodiment has been described in detail above, it is not limited to the above described embodiment, and various modifications and substitutions can be made to the above described embodiment without departing from the scope of the claims.

This application is based on and claims priority to Japanese Patent Application No. 2020-051432, filed to the Japan Patent Office on Mar. 23, 2020, the entire contents of which are incorporated herein by reference.

### DESCRIPTION OF REFERENCE SYMBOLS

| | |
|---|---|
| 1 | spectroscopic analysis system |
| 40 | spectroscopic measurement section |
| 41 | incident section |
| 42 | waveguide |
| 43 | spectroscope |
| 44 | light source |
| 50A, 50B, 50C, 50X, 59 | light emitting element |
| 51X | light emitting diode |
| 52X | fluorescent filter |
| 53X | TIR lens |
| 54X | condenser lens |
| 55X | heat sink |
| 60 | mixer |
| 61 | mirror filter |
| 62 | optical fiber bundle |
| 100 | control device |
| 103 | spectroscopic result retaining section |
| 104 | film thickness calculator |
| 109 | spectroscopic information retaining section |

1. A light source comprising:
a light emitting diode;
a wavelength converter configured to convert a wavelength of light output from the light emitting diode; and
a condenser configured to condense light output from the wavelength converter.

2. The light source as claimed in claim 1, wherein the wavelength of the light output from the light emitting diode is 350 nm or less.

3. A light source comprising:
a plurality of light emitting elements; and
a mixing section configured to mix light output from the plurality of light emitting elements;
wherein each of the plurality of light emitting elements includes:
a light emitting diode;
a wavelength converter configured to convert a wavelength of light output from the light emitting diode; and
a condenser configured to condense light output from the wavelength converter, and
wherein, between the plurality of light emitting elements, the wavelength of the light output from the light emitting diode included in the plurality of light emitting elements differs.

4. The light source as claimed in claim 3, wherein at least one light emitting element among the plurality of light emitting elements includes a light emitting diode that outputs light having a wavelength of 350 nm or less.

5. The light source as claimed in claim 3, wherein at least one light emitting element among the plurality of light emitting elements outputs white light.

6. The light source as claimed in claim 1, wherein light having a wavelength greater than or equal to 250 nm and less than or equal to 1200 nm is output.

7. The light source as claimed in claim 6, wherein a wavelength band of the output light includes a wavelength band greater than or equal to 250 nm and less than or equal to 750 nm.

8. The light source as claimed in claim 1, wherein the wavelength converter includes a plurality of kinds of phosphors.

9. The light source as claimed in claim 1, wherein the wavelength converter includes phosphor particles and a glass configured to retain the phosphor particles.

10. A spectroscopic analysis system comprising:
the light source as claimed in claim 1, the light source being configured to emit the light on an object; and
a spectroscopic measurement section configured to acquire spectroscopic data by dispersing light reflected from the object on which the light source emits the light.

11. The spectroscopic analysis system as claimed in claim 10, wherein the spectroscopic measurement section is configured to acquire the spectroscopic data by dispersing the light from each of a plurality of areas included in a surface of the object, the plurality of areas being different from each other.

12. The spectroscopic analysis system as claimed in claim 10, wherein the spectroscopic measurement section acquires spectrum data of the light as the spectroscopic data and is configured to smooth the spectrum data.

13. A spectroscopic analysis method comprising:
emitting the light to the object from the light source as claimed in claim 1; and
acquiring spectroscopic data by dispersing light reflected from the object on which the light source emits the light.

14. The spectroscopic analysis method as claimed in claim 13, wherein the acquiring of the spectroscopic data includes acquiring the spectroscopic data by dispersing the light from each of a plurality of areas included in a surface of the object, the plurality of areas being different from each other.

15. The spectroscopic analysis method as claimed in claim 13, wherein the acquiring of the spectroscopic data includes acquiring spectrum data of the light as the spectroscopic data and smoothing the spectrum data.
